(19) United States
(12) Patent Application Publication
(10) Pub. No.: US 2017/0309484 A1
(43) Pub. Date: Oct. 26, 2017

(54) Carbon Vacancy Defect Reduction Method for SiC

(71) Applicant: Infineon Technologies AG, Neubiberg (DE)

(72) Inventors: Mihai Draghici, Villach (AT); Romain Esteve, Villach (AT); Craig Arthur Fisher, Villach (AT); Gerald Unegg, Villach (AT); Tobias Hoechbauer, Villach (AT); Christian Heidorn, Villach (AT)

(21) Appl. No.: 15/136,573

(22) Filed: Apr. 22, 2016

(51) Int. Cl. H01L 21/225; H01L 21/311; H01L 21/027; H01L 21/02; H01L 21/324; H01L 21/04

(52) U.S. Cl. CPC H01L 21/2254; H01L 21/324; H01L 21/31111; H01L 21/0455; H01L 21/02115; H01L 21/02271; H01L 21/02266; H01L 21/0273

(57) ABSTRACT

A method of defect reduction for a SiC layer includes activating dopants disposed in the SiC layer, depositing a carbon-rich layer on the SiC layer after activating the dopants, tempering the carbon-rich layer so as to form graphite on the SiC layer, and diffusing carbon from the graphite into the SiC layer. Carbon diffused from the graphite fills carbon vacancies in the SiC layer.

### TECHNICAL FIELD

The instant application relates to SiC technology, and more particularly to reducing carbon vacancy defects in SiC.

### BACKGROUND

Carrier lifetime in thick SiC epitaxial layers is a challenge for the fabrication of low forward voltage bipolar diodes and switches. One root cause of low carrier lifetime in SiC epitaxial layers is the presence of carbon vacancies, commonly referred to as Z₁Z₂ defects, which act as trapping centers. The concentration of Z₁Z₂ defects increases while performing anneals at elevated temperatures above 1750° C.

In order to increase carrier lifetime in SiC epitaxial layers, EDLR (epi defect level reduction) techniques have been proposed. EDLR processes are performed after the high temperature anneal required for dopant activation. Two methods: one based on sacrificial oxidation of the SiC epitaxial layer and the other based on high dose carbon implantation and subsequent annealing, are most often used. Both methods are based on the principle of creating a high concentration of carbon atoms/clusters in a SIC surface region and injecting the carbon atoms/clusters into the thick SiC epitaxial layer via a high temperature anneal in an inert atmosphere. The injected carbon atoms/clusters fill the carbon vacancies created during the high temperature dopant activation annealing. However, such EDLR techniques have high cost.

Further in the case of the SiC oxidation method, oxidation of the SiC epitaxial layer yields silicon dioxide at the top surface and a layer of carbon along the interface between the silicon dioxide and the remaining SiC. The oxidation process is followed by a high temperature anneal above 1500° C. which injects the carbon into the underlying SiC epitaxial layer. Some SiC is consumed by the oxidation process, which must be accounted for in the preceding dopant implantation process. In the case of the high dose carbon implantation approach, a high dose of carbon atoms is implanted into the near surface of the SiC epitaxial layer followed by a high temperature anneal. The implanted region of the SiC epitaxial layer becomes highly damaged and must be removed e.g. by dry etching, which similarly complicates the dopant implantation process in that the implantation process must account for the amount of damaged SiC epitaxial layer to be removed.

### SUMMARY

According to an embodiment of a method of defect reduction for a SiC layer, the method comprises: activating dopants disposed in the SiC layer; depositing a carbon-rich layer on the SiC layer after activating the dopants; tempering the carbon-rich layer so as to form graphite on the SiC layer; and diffusing carbon from the graphite into the SiC layer. Carbon diffused from the graphite fills carbon vacancies in the SiC layer.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a flow diagram of an embodiment of a method of defect reduction for a SiC layer.

FIGS. 2A through 2E illustrate sectional views of the SiC layer during different stages of the defect reduction method, according to one embodiment.

FIGS. 3A through 3F illustrate sectional views of the SiC layer during different stages of the defect reduction method, according to another embodiment.

FIGS. 4A through 4F illustrate sectional views of the SiC layer during different stages of the defect reduction method, according to yet another embodiment.

### DETAILED DESCRIPTION

The embodiments described herein involve the use of deposited carbon and a thermal anneal for diffusing carbon atoms/clusters into the SiC epitaxial layer after dopant activation. The carbon atoms/clusters fill carbon vacancies which formed in the SiC epitaxial layer during the preceding high temperature dopant activation process. By depositing a carbon-rich layer on the SiC layer as a source of carbon for repairing carbon vacancies in the SiC layer, both sacrificial oxidation and high dose carbon implantation of the SiC layer can be avoided. This in turn reduces process cost and simplifies the preceding dopant implantation process in that none of the SiC is consumed by an oxidation process nor is the SiC layer damaged by a high dose carbon implantation.

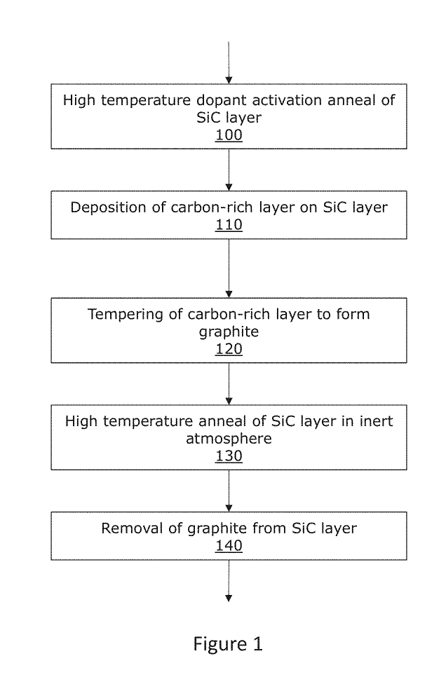

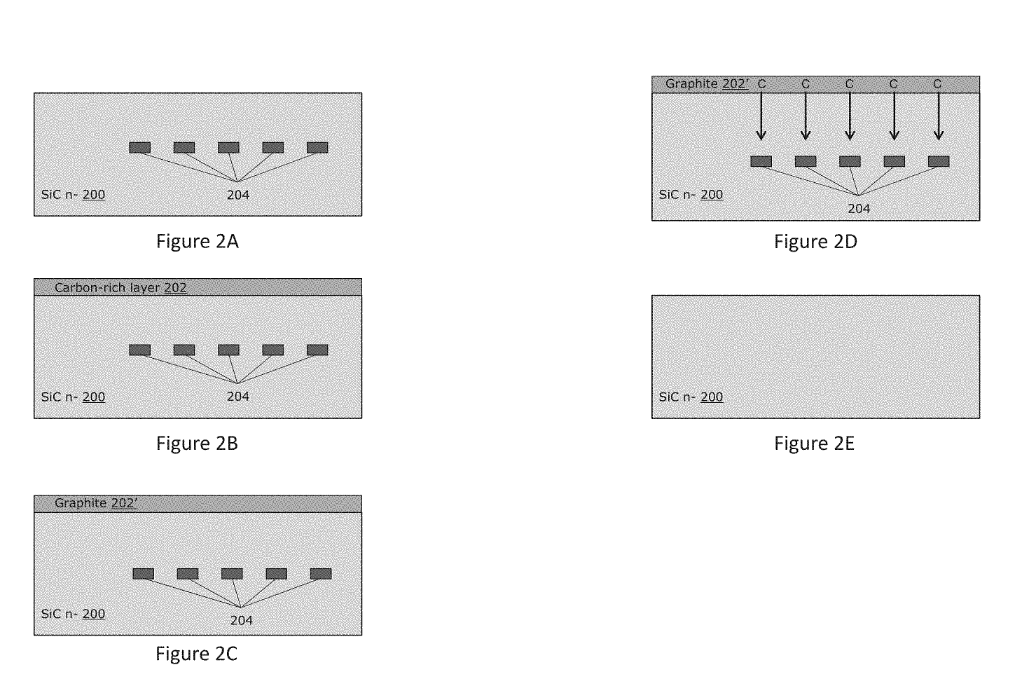

FIG. 1 illustrates an embodiment of a method of defect reduction for a SiC layer 200. FIGS. 2A through 2E illustrate sectional views of the SiC layer 200 during different stages of the defect reduction method. The SiC layer 200 can be part of a SIC substrate, or a SiC epitaxial layer grown on a base semiconductor substrate such as a Si substrate.

The defect reduction method illustrated in FIG. 1 includes activating dopants disposed in the SIC layer 200 (Block 100; FIG. 2A), depositing a carbon-rich layer 202 on the SiC layer 200 after activating the dopants (Block 110; FIG. 2B), tempering the carbon-rich layer 202 so as to form graphite 202′ on the SiC layer 200 (Block 120; FIG. 2C), diffusing carbon (C) from the graphite 202′ into the underlying SiC layer 200, the diffused carbon filling carbon vacancies 204 in the SiC layer 200 (Block 130; FIG. 2D), and removing the graphite 202′ from the SiC layer 200 after carbon is diffused from the graphite 202′ into the SiC layer 200 (Block 140; FIG. 2E).

Dopants are implanted or diffused into the SiC layer 200 prior to deposition of the carbon-rich layer 202. The dopants disposed in the SiC layer 200 are activated prior to deposition of the carbon-rich layer 202 by annealing the SiC layer 200 at a sufficiently high temperature. Dopant activation is the process of obtaining the desired electronic contribution from impurity species in a semiconductor body and is often achieved by the application of thermal energy following ion implantation of dopants. For SiC technology, dopants are often activated at a range between e.g. 1600° C. and 1800° C. Carbon vacancies 204 are generated in the SiC layer 200 at such elevated temperatures. The carbon vacancies 204 facilitate movement of the dopant species from interstitial to substitutional lattice sites, but carbon vacancies which are not filled reduce carrier lifetime. The SiC layer 200 is shown as lightly n-doped (n-) in the figures, but could be more heavily doped (n+) in certain areas or even oppositely p-doped.

The carbon-rich layer 202 is deposited on the SIC layer 200 after activation of the dopants disposed in the SiC layer 200. The carbon-rich layer 202 serves as a source of carbon atoms/clusters which will be diffused into the SiC layer 200 for the purpose of filling the carbon vacancies 204 formed in the SIC layer 200 during the preceding dopant activation process. By depositing a carbon-rich layer 202 on the SiC layer 200 as the source of diffusion carbon, both sacrificial oxidation and high dose carbon implantation of the SiC layer 200 are avoided.

In one embodiment, the carbon-rich layer 202 is a layer of amorphous carbon deposited on the SiC layer 200 by physical vapor deposition (PVD). Amorphous carbon is free, reactive carbon that does not have any crystalline structure. In another embodiment, the layer of amorphous carbon is deposited on the SiC layer 200 by chemical vapor deposition (CVD). In PVD, a pure source material is gasified via evaporation, the application of high power electricity, laser ablation, and a few other techniques. The gasified material condenses on the substrate material to create the desired layer. No chemical reactions take place in the PVD process. In CVD, the source material is mixed with a volatile precursor that acts as a carrier. The mixture is injected into the chamber that contains the substrate material and is then deposited on the substrate. When the mixture is already adhered to the substrate, the precursor eventually decomposes and leaves the desired layer of the source material on the substrate surface. The byproduct is then removed from the chamber via gas flow. The process of decomposition can be assisted or accelerated via the use of heat, plasma, or other processes. In each case, a carbon-rich layer 202 is deposited on the SiC layer 200 instead of being formed by sacrificial oxidation or high dose carbon implantation of the SiC layer 200.

In yet another embodiment, the carbon-rich layer 202 is deposited on the SiC layer 200 by coating the SiC layer 200 with a photoresist. Photoresists are widely used in the semiconductor arts to transfer a pattern onto a photoresist film by exposing the photoresist to light through a mask of the pattern. The photolithographic procedure typically includes coating a base material with photoresist, exposing the resist through a mask to light, developing the resist, etching the exposed areas of the base, and stripping (removing) the remaining resist. A photoresist has four basic components: a polymer; a solvent; sensitizers; and other additives. The polymer either polymerizes or photosolubilizes when exposed to light. Solvents allow the photoresist to be applied by spin-coating. The sensitizers control the photochemical reactions, and additives may be used to facilitate processing or to enhance material properties. Photochemical changes to polymers are necessary to the functionality of a photoresist. Polymers are composed primarily of carbon, hydrogen, and oxygen-based molecules arranged in a repeated pattern. As such, photoresists are carbon-rich and can be used as a source of carbon atoms/clusters for filling carbon vacancies 204 formed in the SiC layer 200 during the preceding dopant activation process.

The carbon-rich layer 202 is tempered to form graphite 202′. Graphite 202′ is a crystalline form of carbon, and therefore is a source of carbon atoms/clusters for filling carbon vacancies 204 formed in the SiC layer 200 during the preceding dopant activation process. Tempering is a process of heat treating the carbon-rich layer 202 so as to form graphite 202′. In one embodiment, the carbon-rich layer 202 is tempered at a range between 700° C. and 1200° C. so as to form graphite 202′.

Carbon from the graphite 202′ is diffused into the underlying SiC layer 200 so as to fill carbon vacancies 204 formed in the SiC layer 200 during the preceding dopant activation process. In one embodiment, carbon from the graphite 202′ is diffused into the SiC layer 200 by annealing the SiC layer 200 above 1500° C. in an inert atmosphere. The graphite 202′ can be removed from the SiC layer 200 after the annealing/carbon diffusion process e.g. by an O₂ plasma or wet carbon etching.

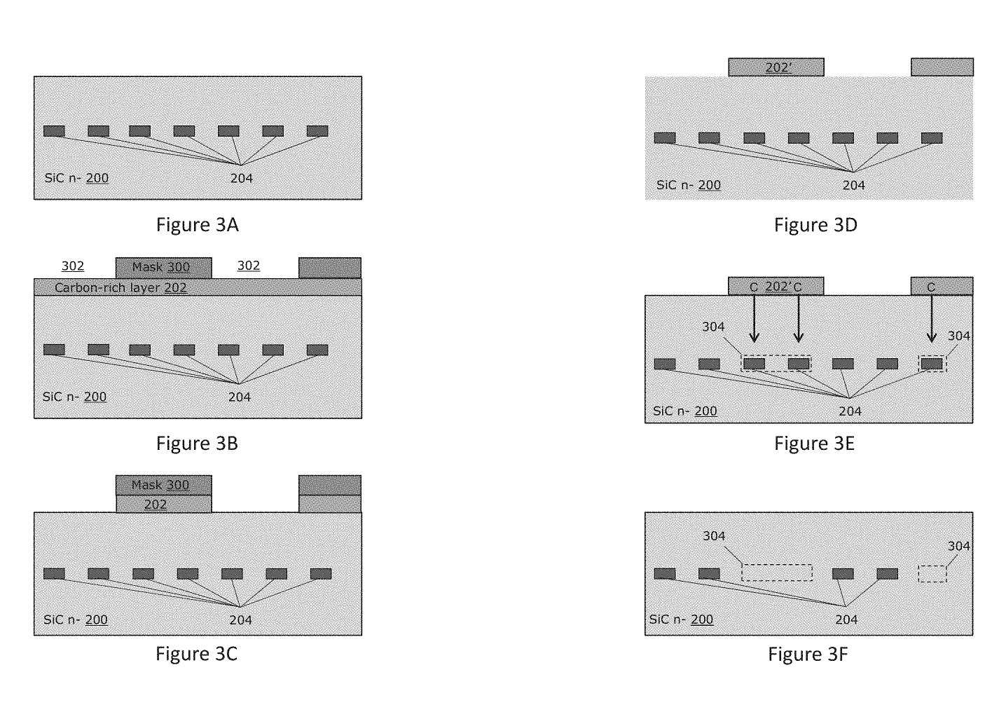

FIGS. 3A through 3F illustrate sectional views of the SiC layer 200 during different ages of the defect reduction method, according to another embodiment.

In FIG. 3A, dopants disposed in the SiC layer 200 are activated by annealing the SiC layer 200 at a range between e.g. 1600° C. and 1800° C. The high temperature dopant activation annealing process results in the formation of carbon vacancies 204 in the SiC layer 200.

In FIG. 3B, a carbon-rich layer 202 is deposited on the SiC layer 200 and a mask 300 is formed on the carbon-rich layer 202. The mask 300 has patterns 302 which are transferred to the underlying carbon-rich layer 202 prior to the graphite-forming tempering process.

In FIG. 3C, the carbon-rich layer 202 (e.g. amorphous carbon or photoresist) is patterned using the mask 300 prior to the tempering process. In the case of an amorphous carbon layer deposited on the SiC layer 200 by PVD or CVD as the carbon-rich layer 202, the mask 300 can be a photosensitive layer and the exposed part of the amorphous carbon layer 202 i.e. the part uncovered by the mask 300 can be patterned with an O₂ plasma etch or wet carbon etching to accurately reproduce the pattern of the overlying photosensitive layer mask 300. In the case of a photoresist layer deposited on the SiC layer as the carbon-rich layer 202, the photoresist can be exposed through the mask 300 to light, developed, and the exposed areas etched by an O₂ plasma etch or wet carbon etching.

In FIG. 3D, the patterned carbon-rich layer 202 is tempered to form a correspondingly patterned graphite 202′ as previously described herein.

In FIG. 3E, carbon (C) from the patterned graphite 202′ is diffused into the SiC layer 200 e.g. by annealing the SiC layer 200 above 1500° C. in an inert atmosphere. The carbon diffused from the patterned graphite 202′ fills carbon vacancies 204 in local areas 304 of the SiC layer 200. The local areas 304 correspond to the patterned carbon-rich layer 202. In one embodiment, the carbon-rich layer 202 is patterned such that carrier lifetime enhancement is provided only at the place where high current gain is needed. Carbon vacancies 204 can remain outside the local areas 304.

In FIG. 3F, the patterned graphite 202′ is removed from the SiC layer 200 e.g. by an O₂ plasma or wet carbon etching after carbon is diffused from the patterned graphite 202′ into the underlying SiC layer 200.

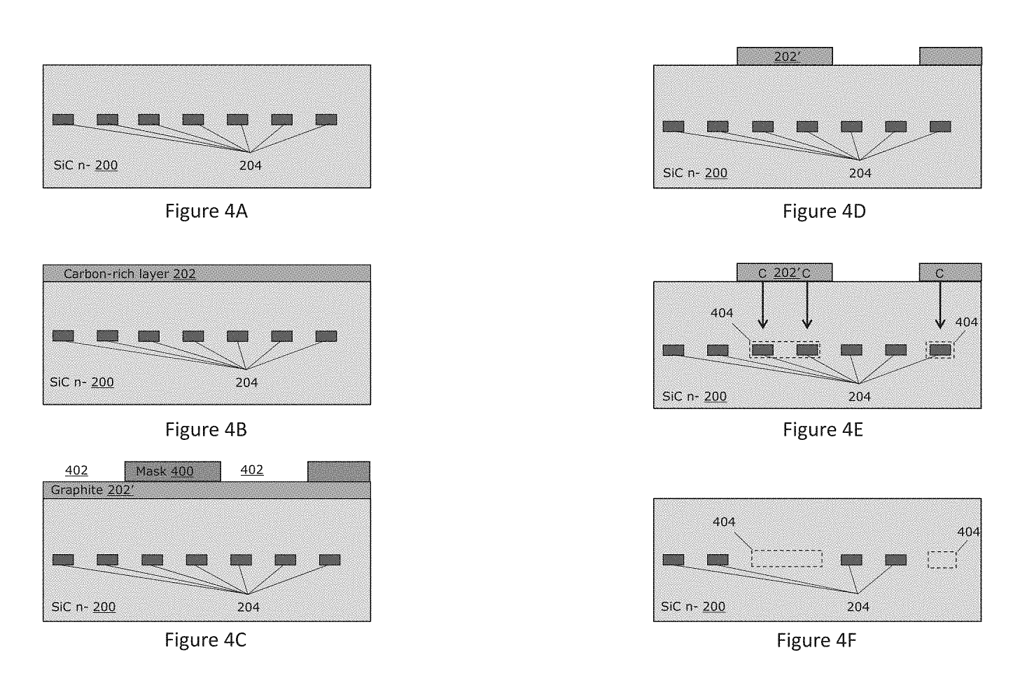

FIGS. 4A through 4F illustrate sectional views of the SiC layer 200 during different stages of the defect reduction method, according to yet another embodiment.

In FIG. 4A, dopants disposed in the SiC layer 200 are activated by annealing the SiC layer 200 at a range between e.g. 1600° C. and 1800° C. The high temperature dopant activation annealing process results in the formation of carbon vacancies 204 in the SiC layer 200.

In FIG. 4B, a carbon-rich layer 202 such as a layer of amorphous carbon or a photoresist is deposited on the SiC layer 200.

In FIG. 4C, the carbon-rich layer 202 is tempered to form graphite 202′ and a mask 400 is formed on the graphite 202′. The mask 400 has patterns 402 which are transferred to the graphite 202′ prior to the diffusion of carbon from the graphite 202′ into the underlying SiC layer 200.

In FIG. 4D, the graphite 202′ is patterned using the mask 400 prior to the carbon diffusion process. The graphite 202′ can be patterned by an O₂ plasma etch or wet carbon etching, for example.

In FIG. 4E, carbon (C) from the patterned graphite 202′ is diffused into the SiC layer 200 e.g. by annealing the SiC layer 200 above 1500° C. in an inert atmosphere. The carbon diffused from the patterned graphite 202′ fills carbon vacancies 204 in local areas 404 of the SiC layer 200 which correspond to the patterned graphite 202′. In one embodiment, the graphite 202′ is patterned such that carrier lifetime enhancement is provided only at the place where high current gain is needed and carbon vacancies 204 can remain outside these local areas 404.

In FIG. 4F, the patterned graphite 202′ is removed from the SiC layer 200 e.g. by an O₂ plasma or wet carbon etching after carbon is diffused from the patterned graphite 202′ into the underlying SiC layer 200.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc, and are also not intended to be limiting. Like terms refer to like elements throughout the description.

As used herein, the terms “having”, “containing”, “including”, “comprising” and the like are open-ended terms that indicate the presence of stated elements or features, but do not preclude additional elements or features. The articles “a”, “an” and “the” are intended to include the plural as well as the singular, unless the context clearly indicates otherwise,

With the above range of variations and applications in mind, it should be understood that the present invention is not limited by the foregoing description, nor is it limited by the accompanying drawings. Instead, the present invention is limited only by the following claims and their legal equivalents.

1. A method of defect reduction for a SiC layer, the method comprising:
activating dopants disposed in the SiC layer;
depositing a carbon-rich layer on the SiC layer after activating the dopants as a source of carbon for repairing carbon vacancies in the SiC layer;
tempering the carbon-rich layer to directly transform the carbon-rich layer into graphite on the SiC layer, wherein the SiC layer is not etched by the graphite formation; and
diffusing carbon from the graphite into the SiC layer, the diffused carbon filling the carbon vacancies in the SiC layer,
wherein the carbon vacancies in the SiC layer are filled by the diffused carbon without performing sacrificial oxidation or high dose carbon implantation of the SiC layer.

2. The method of claim 1, wherein activating the dopants disposed in the SiC layer comprises:
annealing the SiC layer at a range between 1600° C. and 1800° C.

3. The method of claim 1, wherein depositing the carbon-rich layer on the SiC layer comprises:
depositing a layer of amorphous carbon on the SiC layer by physical vapor deposition.

4. The method of claim 3, further comprising:
patterning the layer of amorphous carbon prior to tempering so that carbon subsequently diffused from the patterned layer of amorphous carbon fills carbon vacancies in local areas of the SiC layer, the local areas corresponding to the patterned layer of amorphous carbon.

5. The method of claim 1, wherein depositing the carbon-rich layer on the SiC layer comprises:
depositing a layer of amorphous carbon on the SiC layer by chemical vapor deposition.

6. The method of claim 5, further comprising:
patterning the layer of amorphous carbon prior to tempering so that carbon subsequently diffused from the patterned layer of amorphous carbon fills carbon vacancies in local areas of the SiC layer, the local areas corresponding to the patterned layer of amorphous carbon.

7. The method of claim 1, wherein depositing the carbon-rich layer on the SiC layer comprises:
coating the SiC layer with a photoresist comprising carbon.

8. The method of claim 7, further comprising:
patterning the photoresist prior to tempering so that carbon subsequently diffused from the patterned photoresist fills carbon vacancies in local areas of the SiC layer, the local areas corresponding to the patterned photoresist.

9. The method of claim 1, wherein the carbon-rich layer is tempered at a range between 700° C. and 1200° C. so as to form the graphite.

10. The method of claim 1, wherein diffusing carbon from the graphite into the SiC layer comprises:
annealing the SiC layer above 1500° C. in an inert atmosphere.

11. The method of claim 1, further comprising:
patterning the carbon-rich layer prior to tempering so that carbon subsequently diffused from the patterned carbon-rich layer fills carbon vacancies in local areas of the SiC layer, the local areas corresponding to the patterned carbon-rich layer.

12. The method of claim 1, further comprising:
patterning the graphite prior to diffusing carbon from the graphite into the SiC layer so that carbon subsequently diffused from the patterned graphite fills carbon vacancies in local areas of the SiC layer, the local areas corresponding to the patterned graphite.

13. The method of claim 1, further comprising:
removing the graphite from the SiC layer after carbon is diffused from the graphite into the SiC layer.

14. The method of claim 13, wherein the graphite is removed from the SiC layer by an O₂ plasma or wet carbon etching.

15. The method of claim 1, wherein the SiC layer is a SiC epitaxial layer grown on a Si substrate.
